(19) United States
(12) Patent Application Publication
(10) Pub. No.: US 2024/0365546 A1
(43) Pub. Date: Oct. 31, 2024

(54) MULTIPLE METAL WORD LINE GATES IN A THREE DIMENSIONAL MEMORY ARRAY

(71) Applicant: Micron Technology, Inc., Boise, ID (US)

(72) Inventor: Ramanathan Gandhi, Singapore (SG)

(21) Appl. No.: 18/639,781

(22) Filed: Apr. 18, 2024

Related U.S. Application Data
(60) Provisional application No. 63/498,078, filed on Apr. 25, 2023.

(51) Int. Cl. H10B 43/27; H10B 43/35

(52) U.S. Cl. CPC H10B 43/27; H10B 43/35

(57) ABSTRACT

Methods, systems, and devices for multiple metal word line gates in a three dimensional (3D) memory array are described. A multi-metal control gate may be formed and used to access the memory cells. The metals may be selected such that an electric field induced in the memory cell during access is relatively even across its area. For example, metals having different work functions or resistivities may induce different electric fields. Accordingly, metals may be selected to increase an electric field induced in a planar region in the memory cell relative to if a single metal control gate were implemented such that relatively even electric fields are induced throughout the memory cell. To support formation of the multi-metal control gate, a portion of the metal forming the control gate may be partially etched and replaced with one or more other metals to form the multi-metal control gate.

### CROSS REFERENCE

The present Application for Patent claims priority to U.S. Patent Application No. 63/498,078 by Ramanathan Gandhi, entitled “MULTIPLE METAL WORD LINE GATES IN A THREE DIMENSIONAL MEMORY ARRAY,” filed Apr. 25, 2023, which is assigned to the assignee hereof, and which is expressly incorporated by reference in its entirety herein.

### TECHNICAL FIELD

The following relates to one or more systems for memory, including multiple metal word line gates in a three dimensional (3D) memory array.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports multiple metal word line gates in a three dimensional (3D) memory array in accordance with examples as disclosed herein.

FIG. 2 shows an example of a memory architecture that supports multiple metal word line gates in a 3D memory array in accordance with examples as disclosed herein.

FIG. 3A, 3B, 3C, 3D, and 3E show an example of operations of a manufacturing process that supports multiple metal word line gates in a 3D memory array in accordance with examples as disclosed herein.

FIG. 4 shows an example of operations of a manufacturing process that supports multiple metal word line gates in a 3D memory array in accordance with examples as disclosed herein.

FIG. 5 shows a flowchart illustrating a method or methods that support multiple metal word line gates in a 3D memory array in accordance with examples as disclosed herein.

### DETAILED DESCRIPTION

Some three dimensional (3D) memory arrays (e.g., 3D not-and (NAND) arrays) may include split memory cells. For example, a 3D memory array may include pillars of memory cells that are divided (e.g., split, partitioned) with respective memory cells located on each side of the divided pillars. As such, split memory cells may increase (e.g., double) the bit density of a memory array. However, as a result, each memory cell may be relatively semi-circular (e.g., semi-elliptical) in shape (e.g., have a relatively semi-circular cross-sectional shape). The shape of the split memory cell may result in uneven electric fields being applied throughout the memory cell, such as during access of the memory cell. For example, a higher electric field may be induced in a curved region (e.g., with greater ellipticity) of the memory cell than is induced in a planar region of the memory cell. As such, the planar region may be programmed relatively slow, and a threshold voltage of the cell may be dictated by the planar region. As a result, a higher quantity of pulses, voltages, or both may be used to set the threshold voltage correctly relative to if electric fields were relatively evenly induced throughout (e.g., across) the memory cell. Additionally, during access, the planar region may be a parasitic leakage path. Such issues may limit the scaling of 3D memory arrays (e.g., 3D NAND arrays) and the cost-per-bit benefit of scaled 3D memory arrays as the quantity of levels increases. Therefore, counteracting (e.g., correcting, balancing) the uneven electric fields of semi-circular memory cells may be desirable.

In accordance with examples described herein, a multi-metal control gate (e.g., dual metal control gate) may be formed and used to access split memory cells. The metals may be selected such that an electric field induced across the memory cell during access is relatively even. For example, metals having different work functions (e.g., resistivities) may induce different electric fields (e.g., electric fields having different strengths). Accordingly, metals may be selected to increase an electric field induced in the planar region relative to if a single metal was used to form the control gate such that relatively even (e.g., balanced, equal) electric fields are induced throughout the memory cell. To support this multi-metal control gate formation, a portion of the metal forming the control gate may be partially etched (e.g., removed, such as using a trench that splits the memory cell into two) and replaced with one or more other metals (e.g., deposited, such as using the trench) to form the multi-metal control gate. Therefore, the multi-metal control gate may improve programmability and scalability of memory cells at a relatively low cost, reduce parasitic leakage during access, and reduce access latency and power consumption (e.g., based on reducing the voltages, quantity of pulses, or both used to access split memory cells), among other benefits.

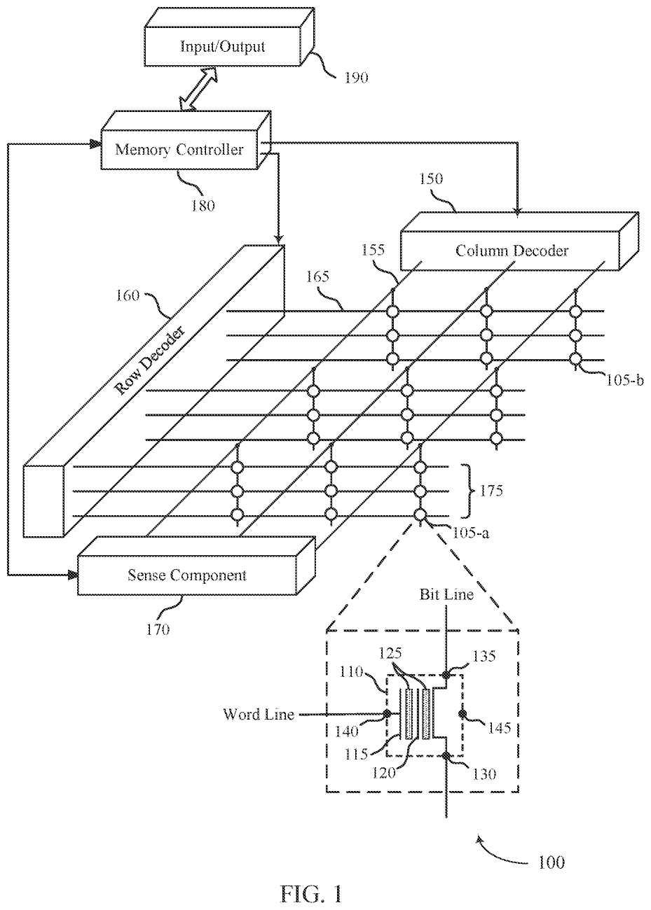

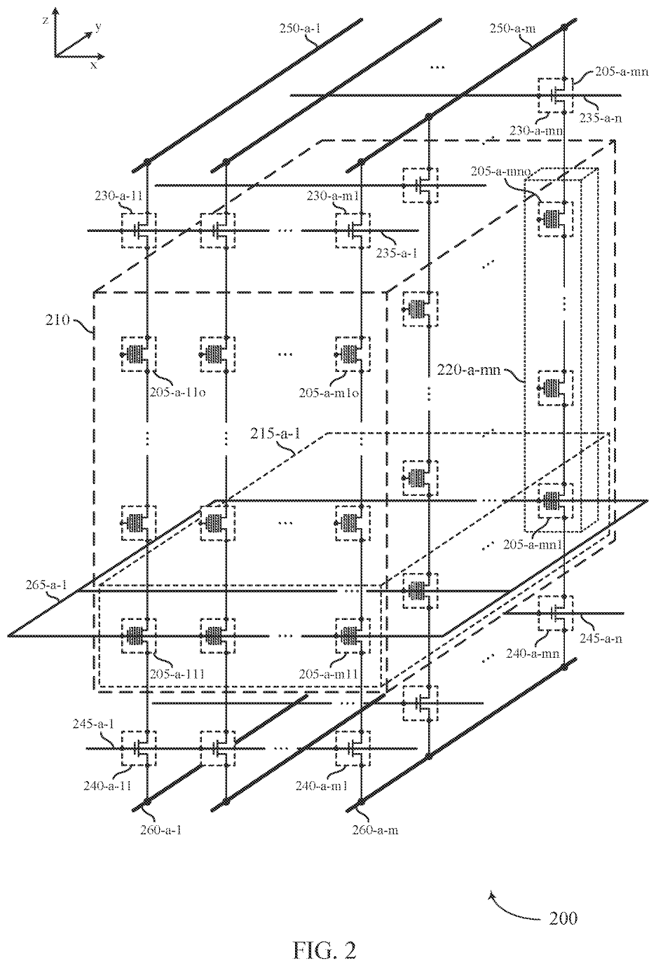

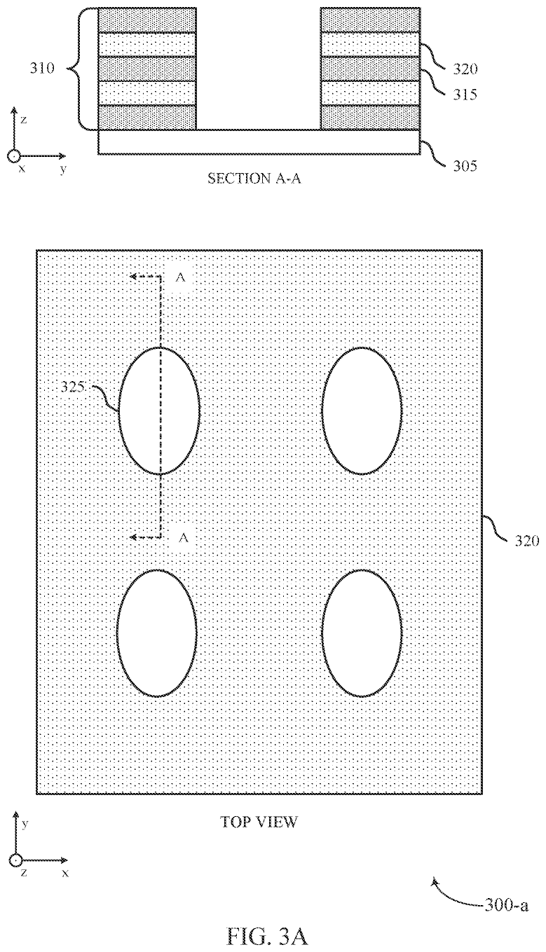

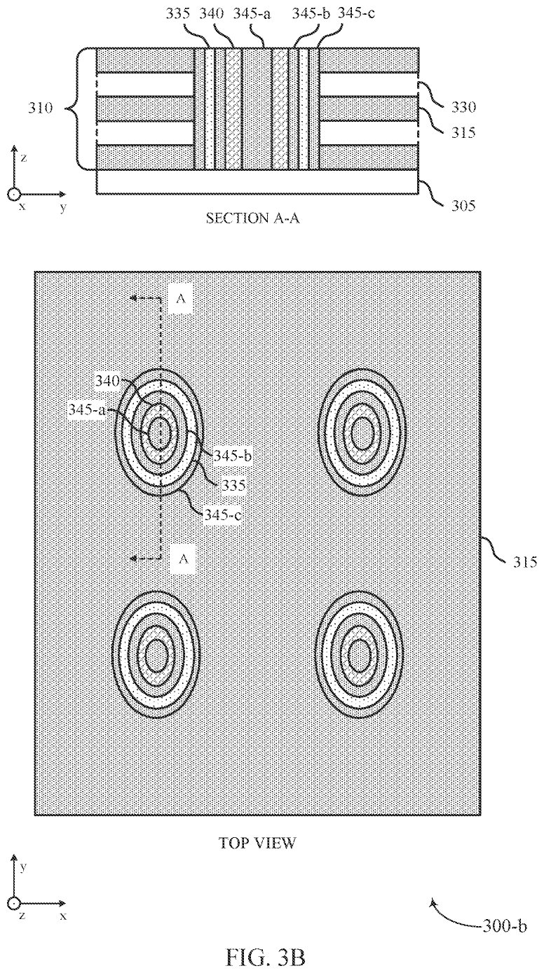

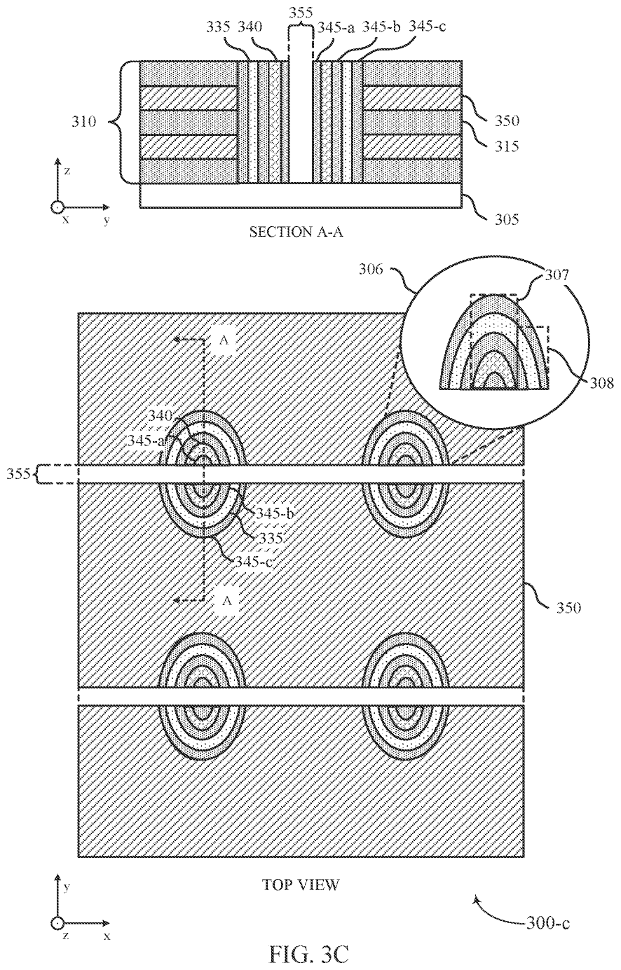

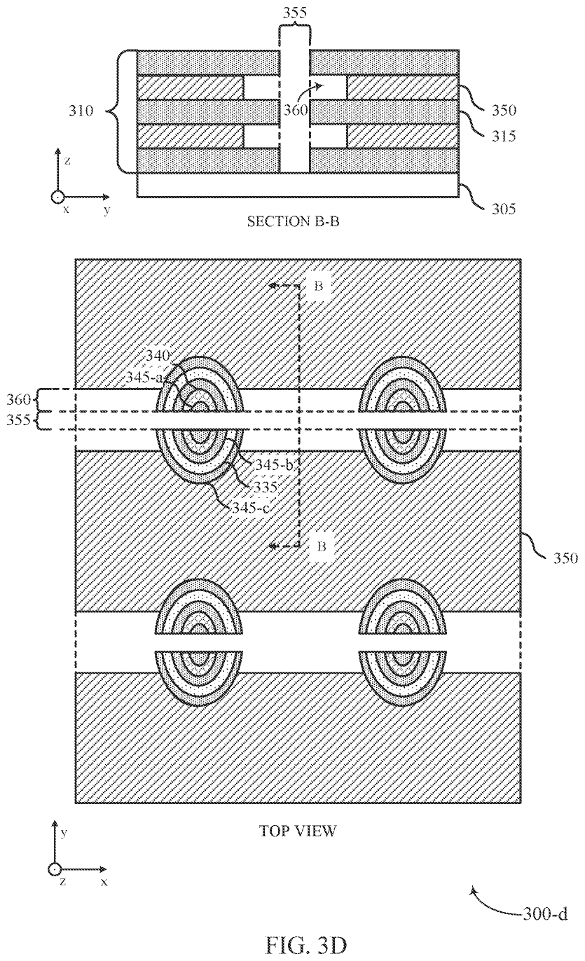

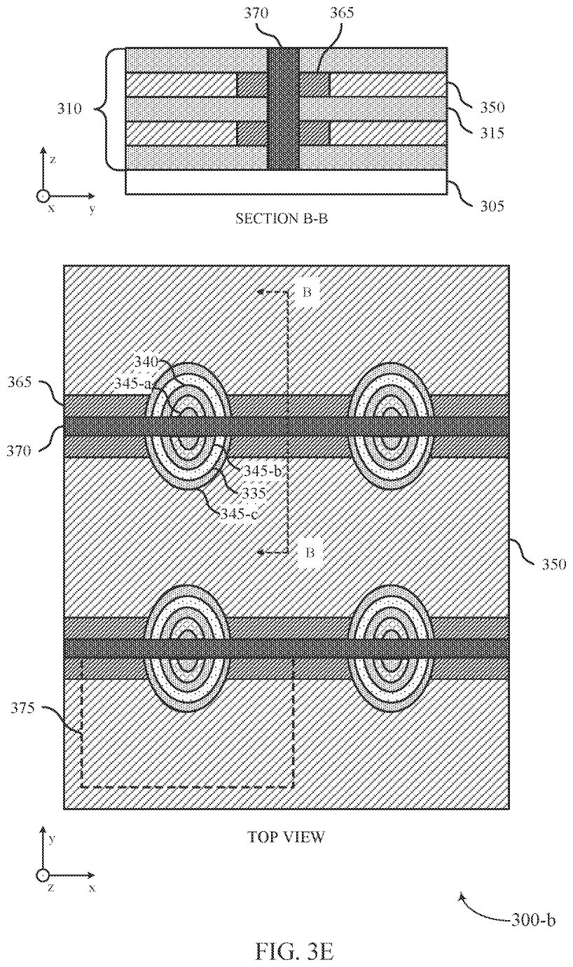

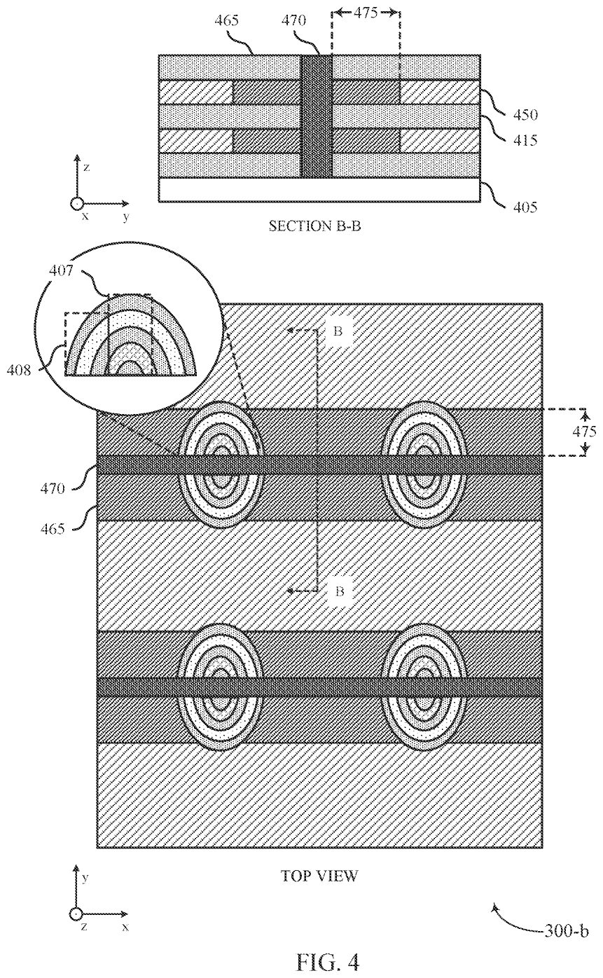

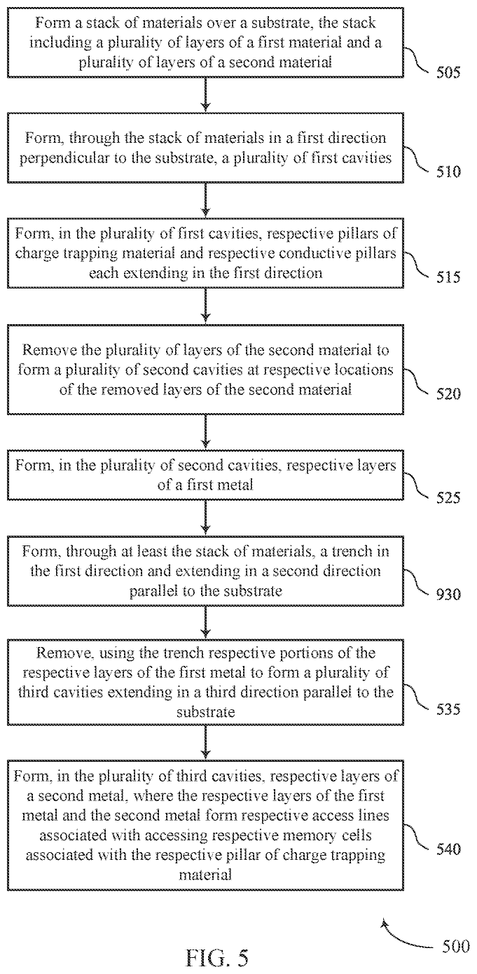

Features of the disclosure are initially described in the context of systems, devices, and circuits with reference to FIGS. 1 and 2. Features of the disclosure are described in the context of operations of a manufacturing process with reference to FIGS. 3 through 4. These and other features of the disclosure are further illustrated by and described in the context of a flowchart that relate to multiple metal word line gates in a 3D memory array with reference to FIG. 5.

FIG. 1 shows an example of a memory device 100 that supports multiple metal word line gates in a 3D memory array in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

In some cases, a memory device 100 may include a 3D memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

A 3D memory array of the memory device 100 may include split memory cells 105. For example, the memory device 100 may include pillars of memory cells 105 along the memory cell stack 175 with respective memory cells 105 of a pillar being located at respective levels of the memory cell stack 175. In some examples, the pillars of memory cells 105 may be split (e.g., divided, partitioned) such that a respective memory cell 105 may be formed (e.g., located) on each side of the split pillar. As such, split memory cells may increase (e.g., double) the bit density of a memory array. However, as a result, each memory cell may be relatively semi-circular (e.g., semi-elliptical) in shape (although other cross-sectional shapes of split memory cells are possible). The shape of the memory cell may result in uneven electric fields being applied throughout the memory cells during access, and consequently, relatively slow programming, and increased risk of parasitic leakage, among other disadvantages.

In accordance with examples described herein, multi-metal control gates (e.g., dual metal control gate), such as included in (e.g., a part of) or coupled with word lines 165, may be formed and used to access the memory cells 105. The metals may be selected (e.g., based on their respective work function, resistivity, or both) such that an electric field induced in the memory cells 105 during access is relatively even. For example, metals may be selected to increase an electric field induced in a planar region of the memory cells 105 (e.g., a cross-sectional region of the memory cells 105 having a relatively linear shape) relative to if a single metal was used to form the control gates such that relatively even (e.g., balanced, equal) electric fields are induced throughout the memory cells 105.

In addition to applicability in memory systems as described herein, techniques for manufacturing multiple metal word line gates in 3D arrays may be generally implemented to support artificial intelligence applications. As the use of artificial intelligence increases to support machine learning, analytics, decision making, or other related applications, electronic devices that support artificial intelligence applications and processes may be desired. For example, artificial intelligence applications may be associated with accessing relatively large quantities of data for analytical purposes and may benefit from memory devices capable of effectively and efficiently storing relatively large quantities of data or accessing stored data relatively quickly. Implementing the techniques described herein may support artificial intelligence techniques by improving scaling and increasing memory density within 3D memory arrays and reducing a latency of accessing split memory cells within 3D memory arrays, among other benefits.

FIG. 2 shows an example of a memory architecture 200 that supports multiple metal word line gates in a 3D memory array in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a 3D array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with a same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget >VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

The memory architecture 200 may include split memory cells 205. For example, the memory architecture 200 may include pillars of memory cells 205 along the z-direction that are split such that each side of the split pillar may form a respective string 220 (although other configurations of strings 220 are possible, such as strings 220 including memory cells 205 on alternating sides of the split pillar along the z-direction). As such, split memory cells 205 may increase (e.g., double) the bit density and storage capacity of the memory architecture 200. However, as a result, each memory cell 205 may be relatively semi-circular (e.g., semi-elliptical) in shape, which may result in uneven electric fields being applied throughout the memory cells 205, and consequently, relatively slow programming, and increased risk of parasitic leakage, among other disadvantages.

To compensate for the shape of the split memory cells 205 resulting in uneven induction of electric fields, multi-metal control gates (e.g., dual metal control gate), such as included in (e.g., part of) or coupled with word lines 265, may be formed and used to access the memory cells 205. The metals may be selected (e.g., based on their respective work function, resistivity, or both) such that an electric field induced in the memory cells 205 during access is relatively even. For example, metals may be selected to increase an electric field induced in a planar region of the memory cells 205 and reduce an electric field induced in a curvature region of the memory cells (e.g., relative to if a single metal control gate were implemented) such that relatively even (e.g., balanced, equal) electric fields are induced throughout the memory cells 205.

FIGS. 3A through 3E illustrate examples of manufacturing operations that support multiple metal word line gates in a 3D memory array in accordance with examples as disclosed herein. For example, FIGS. 3A through 3E may illustrate aspects of a sequence of manufacturing operations for fabricating aspects of a layout 300, which may be a portion of a memory device (e.g., a portion of a memory device 100, a portion of a memory architecture 200). Each view of the FIGS. 3A through 3E may be described with reference to an x-direction, a y-direction, and a z-direction, as illustrated. The manufacturing operations illustrate various cross-sectional views of the layout 300. For example, the manufacturing operations illustrate cross-sectional views of the layout 300 in an yz-plane through the layout 300. The manufacturing operations further illustrate top views of the layout 300 in an xy-plane relative to a layer of a stack of layers 310. Although the layout 300 illustrates examples of certain relative dimensions and quantities of various features, aspects of the layout 300 may be implemented with other relative dimensions or quantities of such features in accordance with examples as disclosed herein.

Operations illustrated in and described with reference to FIGS. 3A through 3E may be performed by a manufacturing system, such as a semiconductor fabrication system configured to perform additive operations such as deposition or bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

FIG. 3A illustrates a portion of a layout 300-a after a first set of one or more manufacturing operations. The first set of manufacturing operations may include forming various structures and materials over a substrate 305. The substrate 305 may be a semiconductor wafer or other substrate over which a stack of layers 310 may be formed (e.g., deposited). The layout 300-a illustrates a top view in the xy-plane relative to a layer of sacrificial material 320 of the stack of layers 310. Section A-A shows a cross-sectional view of a portion of the layout 300-a in the yz-plane.

The stack of layers 310 may include alternating layers of a first material and a second material. For example, the first material in the stack of layers 310 may be a dielectric material 315 and the second material in the stack of layers 310 may be a sacrificial material 320. In some examples, the sacrificial material 320 may be a nitride material and may be subsequently removed (e.g., etched) and replaced by a conductive material to form, for example, word lines (e.g., word lines 165, word lines 265), control gates, or other conductive structures. The quantity of layers depicted in the stack of layers 310 may be for illustrative purposes. For example, the stack of layers 310 may include any quantity of layers of the dielectric material 315 and the sacrificial material 320, including more or less layers than those illustrated.

The first set of manufacturing operations may also include a recess operation (e.g., etch operation). The recess operation may include removing (e.g., etching) a portion of layers of the stack of layers 310. For example, the recess operation may form a recess (e.g., a cavity 325, a hole) through the stack of layers 310 in the z-direction (e.g., in a direction orthogonal or perpendicular to the substrate 305), over the substrate 305. In some examples, the first set of manufacturing operations may include forming multiple cavities 325 through the stack of layers 310, such as an array of cavities 325 be formed in rows extending in the y-direction and in columns extending in the x-direction. In some cases, the cavities 325 may form the basis of a memory array. For example, materials may be formed in the cavities 325 to form pillars of memory cells (e.g., memory cells at respective levels of a 3D memory array) and some associated access circuitry (e.g., conductive pillars, such as to couple memory cells with one or more access lines). It is noted that, while the cavities 325 are depicted as having elliptical cross-sectional shapes, other cross-sectional shapes are possible.

Although the structures and materials are illustrated as being deposited in direct contact with the substrate 305, in some other examples, the layout 300-a may include other materials or components between the structures and materials and the substrate 305, such as interconnection or routing circuitry (e.g., access lines), control circuitry (e.g., transistors, aspects of a local memory controller, decoders, multiplexers), or other structures and materials (e.g., other structures and materials that have been processed in accordance with examples as disclosed herein), which may include various conductor, semiconductor, or dielectric materials between the structures and materials and the substrate 305. For example, the layout 300-a may include a layer including thin-film-transistors (TFTs) between the substrate 305 and the structures and materials, and/or access lines and transistors (e.g., a source line 260, a select line 245, a transistor 240) between the substrate 305 and the structures and materials, among others. In some examples, the substrate 305 itself may include such interconnection or routing circuitry.

FIG. 3B illustrates a portion of a layout 300-b after a second set of one or more manufacturing operations. The second set of manufacturing operations may include forming one or more pillars of materials within each of the cavities 325. For example, each material of the pillar of materials may form a pillar extending in the z-direction orthogonal to the substrate 305 and through the cavities 325, where each pillar includes one or more annuluses (e.g., cylindrical pillars, rings) of material, and where section A-A of layout 300-a shows a cross-sectional view in the yz-plane. The layout 300-b also illustrates a top view in the xy-plane relative to a layer of dielectric material 315 of the stack of layers 310. It is noted that, while the pillars of materials are depicted as having elliptical cross-sectional shapes, other cross-sectional shapes are possible, such as based on the cross-sectional shape of the cavities 325.

To form the pillar of materials, a first dielectric material 345-c may be formed within a cavity 325 such that the first dielectric material 345-c extends through the stack of layers 310 in the z-direction, over the substrate 305. For example, the second set of manufacturing operations may include depositing the first dielectric material 345-c in respective cavities 325 to form respective pillars (e.g., annuluses) of the first dielectric material 345-c. In some examples, the first dielectric material 345-c may be a dielectric material (e.g., that is the same or different than the dielectric material 315), such as silicon oxide, among other dielectric materials.

A charge trapping material 335 may be formed within the annulus of the first dielectric material 345-c such that the charge trapping material 335 extends through the stack of layers 310 in the z-direction, over the substrate 305. For example, the second set of manufacturing operations may include depositing the charge trapping material 335 in respective cavities 325 to form respective pillars (e.g., annuluses) of the charge trapping material 335 (e.g., in contact with the first dielectric material 345-c). In some examples, the charge trapping material 335 may be a material used to form memory cells (e.g., a storage material, a memory cell material, a phase change material, or the like). That is, the charge trapping material 335 may be a material capable of storing a charge indicative of a logic state stored by a memory cell.

A second dielectric material 345-b may be formed within the annuluses of charge trapping material 335 such that the second dielectric material 345-b extends through the stack of layers 310 in the z-direction. For example, the second set of manufacturing operations may include depositing the second dielectric material 345-b in respective cavities 325 to form respective pillars (e.g., annuluses) of the second dielectric material 345-b (e.g., in contact with the charge trapping material 335). In some examples, the second dielectric material 345-b may be a same dielectric material as the first dielectric material 345-c or the dielectric material 315 or may be a different dielectric material.

A conductive material 340 (e.g., a metal material) may be formed within the annuluses of second dielectric material 345-b such that the conductive material 340 extends through the stack of layers 310 in the z-direction. For example, the second set of manufacturing operations may include depositing the conductive material 340 in respective cavities 325 to form respective pillars (e.g., annuluses) of the conductive material 340 (e.g., in contact with the second dielectric material 345-b). Each annulus of conductive material 340 may be used to access a string of memory cells, the string extending in the z-direction along the annulus of conductive material 340. For example, respective memory cells may be formed at each junction of the conductive material 340 and a control gate (e.g., word line), such as formed at locations of the layers of sacrificial material 320, as described with reference to FIGS. 3C through 3E.

A third dielectric material 345-a may be formed within the annuluses of conductive material 340 such that the third dielectric material 345-a extends through the stack of layers 310 in the z-direction. For example, the second set of manufacturing operations may include depositing the third dielectric material 345-a in respective cavities 325 to form respective pillars of the third dielectric material 345-a (e.g., in contact with the conductive material 340). In some cases, the third dielectric material 345-a may be formed as a solid pillar. In some examples, the third dielectric material 345-a may be a same dielectric material as the first dielectric material 345-c, the second dielectric material 345-b, or the dielectric material 315, or may be a different dielectric material.

In some cases, the materials (e.g., materials 335, 340, and 345) of the pillar of materials formed in the cavity 325 may be formed to each partially fill the cavity 325. For example, the dielectric material 345-c may partially fill a first portion of the cavity 325; the charge trapping material 335 may partially fill a remaining portion of the cavity 325 unfilled by the dielectric material 345-c, and so on up through the third dielectric material 345-afilling a remainder of the cavity 325. For instance, each material may be successively deposited (e.g., grown) in the cavities 325 to fill a respective portion of the cavity 325, as depicted. In some cases, forming the annuluses of the pillar of materials may include one or more recess operations. For example, a solid pillar of the first dielectric material may be deposited, filling the cavity 325. A recess operation may remove a portion of the first dielectric material, such as a core of the pillar extending in the z-direction, to form the first dielectric material 345-c with a hollow center. Then, the subsequent material (e.g., charge trapping materials) may be deposited to fill the core of the first dielectric material 345-c. Similar recess operations may be used to remove portions from each subsequent material, to form each of the charge trapping material 335, second dielectric material 345-b, conductive material 340, and third dielectric material 345-a.

The second set of manufacturing operations may also include a recess operation. The recess operation may include removing (e.g., exhuming) each layer of sacrificial material 320 from the stack of layers 310, such as using replacement gate techniques. For instance, to remove and deposit some materials within the memory device, the manufacturing system may form one or more holes (not shown) at various locations of the memory device. For example, each of the layers of the sacrificial material 320 may be exposed via the one or more holes such that the sacrificial material 320 may be exhumed. Accordingly, exhuming the sacrificial material 320 may form, at locations of each of the exhumed layers, a recess (e.g., a cavity 330) through the stack of layers 310 in the x-direction and the y-direction (e.g., in the xy-plane), parallel to the substrate 305. Alternatively, the sacrificial material 320 may be removed from the stack of layers 310 using a trench 355, as described with reference to FIG. 3C. In some examples, the cavities 330 may be formed after forming the trench 355 (e.g., using the one or more holes).

FIG. 3C illustrates a portion of a layout 300-c after a third set of one or more manufacturing operations. The third set of manufacturing operations may include forming a trench 355 (e.g., slit, cavity) through the stack of layers 310 in the z-direction and extending in the x-direction. The layout 300-c also illustrates a top view in the xy-plane relative to a layer of first metal 350 deposited in the cavities 330.

In some cases, the trench 355 may extend through each of the pillars of materials (e.g., each of the respective annuluses) in the x-direction. Accordingly, each of the pillars of materials may be separated into a first pillar (e.g., semicircular pillar) of materials on a first side of the trench and a second pillar of materials on a second side of the trench. For example, each of the first pillar and second pillar may have their own semicircular halves (e.g., semi-elliptical halves, among other cross-sectional shapes) of the charge trapping material 335, second dielectric material 345-b, conductive material 340, and third dielectric material 345-a, extending in the z-direction.

The third set of manufacturing operations may also include forming (e.g., depositing) a first metal 350 (e.g., into each of the cavities 330, as described with reference to FIG. 3B. In some cases, the first metal 350 may be deposited using the one or more holes via which the sacrificial material 320 was exhumed. For example, after removing the sacrificial material 320, each of the cavities 330 may be exposed such that the first metal 350 may be deposited, filling the cavities 330. Alternatively, in some cases, the first metal 350 may be deposited using the trench 355. For example, each of the cavities 330 may be exposed to the trench 355 such that that the first metal 350 may be deposited, filling the cavities 330. In some examples, the trench 355 may be formed after the deposition of the first metal 350 (e.g., may be formed through layers of the first metal 350).

At each layer, the first metal 350 may be a part of a control gate for a respective memory cell formed at the junction of each control gate and pillar of conductive material 340. For example, the control gate may be or be a part of an access line (e.g., a word line) for accessing the memory cells coupled with the first metal 350.

Each of the first pillar and the second pillar may be associated with a respective set of one or more memory cells throughout the stack of layers 310. For example, a memory cell, as illustrated by illustration 306, may correspond to a portion of the halved charge trapping material 335 that is located at a junction between the halved pillar of conductive material 340 and the layer of the first metal 350. Such a memory cell may be referred to as a split memory cell. The memory cell may be separated from the conductive material 340 and the first metal 350 by the halved second dielectric material 345-b and the halved first dielectric material 345-c, respectively. In some examples, the dielectric materials 345-a and 345-b may be considered as being a part of the memory cell. Due to the curvature of each annulus of material, the memory cell may include a curved region 307 (e.g., with a high degree of ellipticity or curvature) and one or more planar regions 308 (e.g., with a low degree of ellipticity or curvature relative to the curved region 307). Due to the curvature of the memory cells, electric fields created (e.g., induced) in the memory cells, such as part of access operations, may be relatively uneven.

For example, access circuitry (e.g., a control gate, the pillar of conductive material 340) may create (e.g., induce) a relatively stronger electric field in the curved region 307 due to the high degree of ellipticity. In contrast, the access circuitry may create (e.g., induce) a relatively weaker electric field in the planar region 308 due to the low degree of ellipticity. Accordingly, due to the uneven electric field, the planar region 308 may be slow to program compared to the curved region 307, leading to increased program times, power consumption, or both. For example, the threshold voltage VT of the memory cell may be based on (e.g., dictated by) the planar region 308, which may result in a higher quantity of voltage pulses used to program the memory cell to a desired logic state. Further, the planar region 308 may lead to parasitic leakage (e.g., voltage leakage) and consequently a reduced memory window.

In some cases, to counteract the uneven electric field caused by the curvature of the memory cells, the control gate may include additional metals (e.g., a second metal 365, as described with reference to FIG. 3E) with different characteristics (e.g., resistivity, work function) than the first metal 350. For example, a second metal may be used to create a stronger electric field than the first metal. The second metal may be formed near the planar region 308 such that the proximity of the second metal to the planar region 308 may create a stronger electric field in the planar region 308 relative to if a single metal were used for the control gate. Thus, the electric field caused (e.g., created, induced) by the control gate including multiple metals, such as a control gate 375 including the first metal 350 and a second metal 365 as described with reference to FIG. 3E, at the planar region 308 may be approximately equal to (e.g., with negligible variance) the electric field caused by the control gate at the curved region 307.

For example, the VT of a memory cell may be based on a flat band voltage of the memory cell, where the flat band voltage may be determined based on Equation 1, as follows:

$${V}_{FB} = {Φ}_{m} - {Φ}_{S} \qquad ( 1 )$$

In Equation 1 above, V_{FB} is the flat band voltage, Φₘ is the gate metal work function (e.g., the work function of the control gate), and Φₛ is the semiconductor work function. VT may be determined based on Equation 2, as follows:

$$VT = {V}_{FB} - 2 {Φ}_{B} - \frac{{Q}_{Si}}{{C}_{ox}} \qquad ( 2 )$$

In Equation 2 above, Φ_{B} is the bulk potential, Q_{Si} is the intrinsic source charge (e.g., of a MOSFET n-channel transistor), and Cₒₓ is the oxide capacitance per unit area. Accordingly, by increasing the gate metal work function Φₘ, V_{FB} may be increased, and by increasing V_{FB}, VT may be increased.

Due to the geometry of a split memory cell, the planar region 308 may be associated with a lower VT than the curved region 307. Accordingly, by increasing the work function of the control gate near the planar region 308 relative to the work function of the control gate near the curved region 307, the VT of the planar region 308 may be increased such that the VT of the planar region 308 may be approximately equal to the VT of the curved region 307.

FIG. 3D illustrates a portion of a layout 300-d after a fourth set of one or more manufacturing operations. The fourth set of manufacturing operations may include a recess operation to remove a portion of the first metal 350 at each layer of the first metal 350. For example, a respective cavity 360 (e.g., a recess) may be etched into each layer of the first metal 350, each cavity extending in the y-direction parallel to the substrate 305, where section B-B of layout 300-d shows a cross-sectional view in the yz-plane. The layout 300-d also illustrates a top view in the xy-plane relative to a layer of first metal 350 deposited in the cavities 330.

In some cases, the portions of the first metal 350 may be removed using the trench 355. For example, each layer of the first metal 350 may be exposed to the trench 355 such that that the first metal 350 may be etched, forming the cavities 360. Accordingly, a portion of the pillar of materials (e.g., the first dielectric material 345-c) may be exposed to the cavities 360.

FIG. 3E illustrates a portion of a layout 300-e after a fifth set of one or more manufacturing operations. The fifth set of manufacturing operations may include forming (e.g., depositing) a second metal 365 into each of the cavities 360, as described with reference to FIG. 3D. For example, the second metal 365 may be deposited using the trench 355, filling the cavities 360. At each layer, the first metal 350 may be a part of a control gate 375 for a respective memory cell formed at the junction of each control gate 375 and pillar of conductive material 340. In some examples, each control gate 375 may be a part of an access line (e.g., a word line) coupled with the memory cell. For example, a respective word line, such as a word line 265, may be formed from the first metal 350. A portion of the word line may be etched such that the second metal 365 may be deposited in the cavities 360. As a result, in some cases, the second metal 365 may be included in the word line. That is, the word line may be a multi-metal word line. In some examples, the formation of the second metal 365 may be local to the control gates 375. In some examples, the formation of the second metal 365 may extend a length of the word line.

In some cases, the first metal 350 may be a metal with a lower work function (e.g., the amount of energy used to move an electron from a surface of the metal) relative to a work function of the second metal 365, a higher resistivity relative to a resistivity of the second metal 365, or a combination thereof. For example, the second metal 365 may have smaller resistivity than the first metal 350 and a greater work function than the first metal 350. Various metals having varying work functions and resistivities are possible for selection as the first metal 350 and the second metal 365. For instance, examples of metals and their respective work functions shown in “( ) ” may include: yttrium (3.1), magnesium (3.66), aluminum (4.1), manganese (4.1), lead (4.2), tantalum (4.2), silver (4.25), titanium (4.33), zinc (4.33), tungsten (4.5), titanium nitride (4.5), iron (4.5), molybdenum (4.6), copper (4.6), ruthenium (4.7), cobalt (5.0), palladium (5.12), nickel (5.15), and platinum (5.65), among other possible metals.

Various combinations of metals for the first metal 350 and the second metal 365 may be selected with the work function of the metal for the first metal 350 being lower than the work function of the metal for the second metal 365. Accordingly, the qualities of the second metal may create a stronger electric field in the planar region 308 of the memory cells relative to the electric field that the first metal 350 creates in the planar region 308. For example, due to the proximity of the second metal 365 to the planar region 308, the work function of the control gate 375 near the planar region 308 may be greater than the work function of the control gate 375 near the curved region 307. Thus, the electric field caused by the multi-metal control gate 375 at the planar region 308 may be approximately equal to (e.g., with negligible variance) the electric field caused by the multi-metal control gate 375 at the curved region 307. Consequently, the programming of each region may occur at a similar rate, thereby reducing a latency of programming the memory cells, and parasitic leakage may be reduced. Additionally, the quantity of voltage pulses used to program the memory cells may be reduced, which may reduce power consumption, among other benefits.

In some examples, the metals for the first metal 350 and the second metal 365 may be selected based on one or more dimensions of the curved region 307 and the planar region 308. For example, memory cells of different memory devices may have different degrees of curvature within the curved region 307 and the planar region 308. As such, a difference in electric fields induced in the curved region 307 relative to the planar region 308 may be specific to the memory cells of a given memory device. Accordingly, metals may be selected for the multi-metal control gate 375 having relative differences in work functions that compensate for the difference in electric fields induced in the regions of the memory cells that is specific to the dimensions of the regions of the memory cells.

In some cases, the control gate 375 may include one or more additional metals (e.g., a third metal, a fourth metal, and so on). For example, a portion of the second metal 365 may be removed (e.g., etched) to create cavities in each control gate, the cavities exposed to the trench 355. Each of the cavities may be filled with a third metal, forming a control gate with a third word line of the third metal. Alternatively, a portion of the cavities 360 may be filled with the second metal 365 and one or more additional metals may be deposited in a remaining portion of the cavities 360. In some cases, the third metal may be adjacent to a third region of the memory cells, such as a region with less curvature than the planar region 308 (e.g., a region approaching the trench 355 in the y-direction). Accordingly, the third metal may have a smaller resistivity than the first metal 350 and the second metal 365, and a greater work function than the first metal 350 and the second metal 365.

Each region of the memory cell may also have a respective VT. For example, an increase in work function may result in a higher VT while a decrease in work function may result in a lower VT. Therefore, increasing the work function of the control gate 375 near the planar region may increase the VT of the planar region while decreasing the work function of the control gate 375 near the curved region may decrease the VT of the curved region.

In some cases, hybrid metallization (e.g., a dual control gate) can provide less resistance at a reduced cost. For example, while low-resistance materials have relatively high material costs, a limited portion of the control gate 375 may utilize the low-resistance materials to reduce the amount of low-resistance materials. The remaining portion of the control gate 375 may utilize lower cost, higher resistance materials to maintain a lower cost overall. Therefore, compared to a single, homogenous material, a multi-metal (e.g., dual) control gate may provide a memory cell with lower resistance and lower material costs as cells adapted to 3D memory scaling.

In some cases, the fifth set of manufacturing operations may include forming (e.g., depositing) a dielectric material 370 into the trench 355. For example, each memory cell (e.g., a first memory cell and a second memory cell) associated with the pillar of materials may be separated by the dielectric material 370, which may extend through the stack of materials in the z-direction along the x-direction.

FIG. 4 illustrate examples of operations of a manufacturing process that supports multiple metal word line gates in a 3D memory array in accordance with examples as disclosed herein. For example, FIG. 4 may illustrate aspects of a sequence of manufacturing operations for fabricating aspects of a layout 400, which may be a portion of a memory device. The views of FIG. 4 may be described with reference to an x-direction, a y-direction, and a z-direction, as illustrated. The manufacturing operations illustrate various cross-sectional views of the layout 400, such as a section B-B showing a cross-sectional view of a portion of the layout 400 in the yz-plane. Additionally, the layout 400 illustrates a top view in the xy-plane relative to a layer at which a multi-metal control gate is formed.

The manufacturing operations may include the first, second, and third set of manufacturing operations as described with reference to FIGS. 3A through 3C, such as to form: a stack of layers including a dielectric material 415 (e.g., a dielectric material 315) over a substrate 405 (e.g., a substrate 305); pillars of split memory cells including curved regions 407 (e.g., curved regions 307) and planar regions 408 (e.g., planar regions 308); and multi-metal control gates including at least a first metal 450 (e.g., first metal 350) and a second metal 465 (e.g., second metal 365), the multi-metal control gates formed using a trench (e.g., trench 355) in which a dielectric material 470 (e.g., dielectric material 370) is deposited.

However, a fourth set of manufacturing operations, as described with reference to FIG. 3D, may include etching a different quantity of the first metal 450 to form cavities 360 having different depths, and a fifth set of manufacturing operations, as described with reference to FIG. 3E, may include depositing a different quantity of the second metal 465. For example, in the example of FIG. 4, the fourth set of manufacturing operations may include etching a greater portion of the first metal 450 to form deeper cavities (e.g., in the y-direction). Additionally, the fifth set of manufacturing operations may include depositing a greater portion of the second metal 465.

In some cases, a depth 475 of the cavities 360 may be variable based on the characteristics (e.g., dimensions) of a given memory device. For example, the depth 475 of the cavities (e.g., the cavities 360, and thus the quantity of the first metal 450 to remove) may be dynamically determined based on the curvature of the memory cells (e.g., the dimensions of the curved regions 407 and planar regions 408). Based on the curvature of the memory cells, an analysis may be performed to determine the depth 475 of the cavities (e.g., a depth ratio between the first metal 450 and the second metal 465) that may create an approximately even distribution of electric fields across the memory cell (e.g., between the planar region 408 and the curved region 407). For example, the depth 475 of the cavities may be based at least in part on one or more dimensions of the memory cells, such as a length of the memory cells in the y-direction, a width of the memory cells in the x-direction, a curvature of the memory cells (e.g., radii of the memory cell), among others.

In some cases, the analysis may also determine a quantity of metals (e.g., how many metals for hybrid metallization of the control gate) and which metals to use (e.g., based on their respective resistances and work functions, among other quantities). In some examples, the depth 475 of the cavities may also be impacted by the selected metals and the quantity of metals. For example, hybrid metallization with three metals may cause a greater amount of the first metal 450 to be removed, while hybrid metallization with two metals may cause a lesser amount of the first metal 450 to be removed.

FIG. 5 shows a flowchart illustrating a method 500 that supports multiple metal word line gates in a 3D memory array in accordance with examples as disclosed herein. The operations of method 500 may be implemented by a manufacturing system or one or more controllers associated with a manufacturing system. For example, the operations of method 500 may be performed by a manufacturing system as described with reference to FIGS. 3A through 4. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include forming a stack of materials over a substrate, the stack including a plurality of layers of a first material and a plurality of layers of a second material. The operations of 505 may be performed in accordance with examples as disclosed herein.

At 510, the method may include forming, through the stack of materials in a first direction perpendicular to the substrate, a plurality of first cavities. The operations of 510 may be performed in accordance with examples as disclosed herein.

At 515, the method may include forming, in the plurality of first cavities, respective pillars of charge trapping material and respective conductive pillars each extending in the first direction. The operations of 515 may be performed in accordance with examples as disclosed herein.

At 520, the method may include removing the plurality of layers of the second material to form a plurality of second cavities at respective locations of the removed layers of the second material. The operations of 520 may be performed in accordance with examples as disclosed herein.

At 525, the method may include forming, in the plurality of second cavities, respective layers of a first metal. The operations of 525 may be performed in accordance with examples as disclosed herein.

At 530, the method may include forming, through at least the stack of materials, a trench in the first direction and extending in a second direction parallel to the substrate. The operations of 530 may be performed in accordance with examples as disclosed herein.

At 535, the method may include removing, using the trench, respective portions of the respective layers of the first metal to form a plurality of third cavities extending in a third direction parallel to the substrate. The operations of 535 may be performed in accordance with examples as disclosed herein.

At 540, the method may include forming, in the plurality of third cavities, respective layers of a second metal, where the respective layers of the first metal and the second metal form respective access lines associated with accessing respective memory cells associated with the respective pillar of charge trapping material. The operations of 540 may be performed in accordance with examples as disclosed herein.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a stack of materials over a substrate, the stack including a plurality of layers of a first material and a plurality of layers of a second material; forming, through the stack of materials in a first direction perpendicular to the substrate, a plurality of first cavities; forming, in the plurality of first cavities, respective pillars of charge trapping material and respective conductive pillars each extending in the first direction; removing the plurality of layers of the second material to form a plurality of second cavities at respective locations of the removed layers of the second material; forming, in the plurality of second cavities, respective layers of a first metal; forming, through at least the stack of materials, a trench in the first direction and extending in a second direction parallel to the substrate; removing, using the trench, respective portions of the respective layers of the first metal to form a plurality of third cavities extending in a third direction parallel to the substrate; and forming, in the plurality of third cavities, respective layers of a second metal, where the respective layers of the first metal and the second metal form respective access lines associated with accessing respective memory cells associated with the respective pillar of charge trapping material.

Aspect 2: The method or apparatus of aspect 1, further including operations, features, circuitry, logic, means, or instructions, or any combination thereof for forming, after forming the respective layers of the second metal, a dielectric material in the trench.

Aspect 3: The method or apparatus of any of aspects 1 through 2, where forming the trench includes operations, features, circuitry, logic, means, or instructions, or any combination thereof for forming the trench through the respective pillars of charge trapping material and the respective conductive pillars, each respective pillar of charge trapping material being separated into a first pillar of charge trapping material on a first side of the trench and a second pillar of charge trapping material on a second side of the trench, where the first pillar of charge trapping material is associated with a first set of the respective memory cells and the second pillar of charge trapping material is associated with a second set of the respective memory cells.

Aspect 4: The method or apparatus of aspect 3, further including operations, features, circuitry, logic, means, or instructions, or any combination thereof for determining, based at least in part on one or more dimensions of the respective first pillars of charge trapping material, a depth of one or more of the plurality of third cavities, where removing the respective portions of the respective layers of the first metal is based at least in part on determining the depth.

Aspect 5: The method or apparatus of any of aspects 1 through 4, further including operations, features, circuitry, logic, means, or instructions, or any combination thereof for determining, based at least in part on one or more dimensions of a planar region of the respective memory cells, one or more dimensions of a curved region of the respective memory cells, or both, a quantity of the first metal to remove, where removing the respective portions of the respective layers of the first metal is based at least in part on determining the quantity.

Aspect 6: The method or apparatus of aspect 5, further including operations, features, circuitry, logic, means, or instructions, or any combination thereof for selecting, based at least in part on the one or more dimensions of the curved region of the respective memory cells, the first metal to form in the plurality of second cavities based at least in part on a first electric field created by the first metal and selecting, based at least in part on one the one or more dimensions of the planar region of the respective memory cells, the second metal to form in the plurality of third cavities based at least in part on a second electric field created by the second metal, where the second electric field is stronger than the first electric field.

Aspect 7: The method or apparatus of any of aspects 1 through 6, further including operations, features, circuitry, logic, means, or instructions, or any combination thereof for forming, in the plurality of third cavities, respective layers of one or more additional metals, where the respective layers of the first metal, the second metal, and the one or more additional metals form the respective access lines associated with accessing the respective memory cells associated with the respective pillar of charge trapping material.

Aspect 8: The method or apparatus of any of aspects 1 through 6, further including operations, features, circuitry, logic, means, or instructions, or any combination thereof for removing, using the trench, respective portions of the respective layers of the second metal to form a plurality of fourth cavities extending in the third direction and forming, in the plurality of fourth cavities, respective layers of one or more additional metals, where the respective layers of the first metal, the second metal, and the one or more additional metals form the respective access lines associated with accessing the respective memory cells associated with the respective pillar of charge trapping material.

Aspect 9: The method or apparatus of any of aspects 1 through 8, where each of the respective access lines associated with accessing respective memory cells include a respective control gate that includes the first metal and the second metal.

Aspect 10: The method or apparatus of any of aspects 1 through 9, where the first metal is associated with a first work function and the second metal is associated with a second work function greater than the first work function.

Aspect 11: The method or apparatus of any of aspects 1 through 10, where the first metal is associated with a first resistivity and the second metal is associated with a second resistivity different than the first resistivity.

Aspect 12: The method or apparatus of any of aspects 1 through 11, where each third cavity is adjacent to respective locations of one or more of the plurality of first cavities.

Aspect 13: The method or apparatus of any of aspects 1 through 12, further including operations, features, circuitry, logic, means, or instructions, or any combination thereof for forming, in each of the plurality of first cavities, one or more respective pillars of dielectric material extending in the first direction, where each third cavity is adjacent to a pillar of dielectric material separating a respective pillar of charge trapping material and the first metal.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 14: An apparatus, including: a conductive pillar extending in a first direction perpendicular to a substrate and through a plurality of levels of memory cells located over the substrate, the conductive pillar coupled with two or more respective memory cells at each of the plurality of levels; a dielectric material extending in a second direction parallel to the substrate, the dielectric material separating a first memory cell of the two or more respective memory cells from a second memory cell of the two or more respective memory cells at each level of the plurality of levels; and a plurality of access lines extending in the second direction and associated with accessing the plurality of levels of memory cells, where each access line of the plurality of access lines coupled with a respective memory cell includes: a first metal associated with a first resistivity; and a second metal associated with a second resistivity different than the first resistivity.

Aspect 15: The apparatus of aspect 14, further including: a first pillar of charge trapping material extending in the first direction and associated with the first memory cell of the two or more respective memory cells at each level of the plurality of levels; and a second pillar of charge trapping material extending in the first direction and associated with the second memory cell of the two or more respective memory cells at each level of the plurality of levels.

Aspect 16: The apparatus of any of aspects 14 through 15, where each access line of the plurality of access lines includes a respective gate including the first metal and the second metal.

Aspect 17: The apparatus of any of aspects 14 through 16, where a first length of the first metal in a third direction parallel to the substrate and perpendicular to the second direction and a second length of the second metal in the third direction are based at least in part on one or more dimensions of a planar region of the respective memory cells, one or more dimensions of a curved region of the respective memory cells, or both.

Aspect 18: The apparatus of any of aspects 14 through 17, where the first metal is configured to create a first electric field and the second metal is configured to create a second electric field that is stronger than the first electric field.

Aspect 19: The apparatus of any of aspects 14 through 18, where the first metal is associated with a first work function and the second metal is associated with a second work function different than the first work function.

Aspect 20: The apparatus of any of aspects 14 through 19, where each access line of the plurality of access lines includes one or more additional metals different than the first metal and the second metal.

Aspect 21: The apparatus of any of aspects 14 through 20, further including: one or more pillars of dielectric material extending through the plurality of levels of memory cells in the first direction, the first metal and the second metal in contact with a pillar of dielectric material located between a respective memory cell and the first metal and the second metal.

Aspect 22: The apparatus of any of aspects 14 through 21, where the first metal is configured to create a first electric field and the second metal is configured to create a second electric field stronger than the first electric field.

An apparatus is described. The following provides an overview of aspects of the apparatus as described herein:

Aspect 23: An apparatus, including: a conductive pillar extending in a first direction through a plurality of levels of memory cells and coupled with two or more respective memory cells at each of the plurality of levels; a dielectric material extending in a second direction perpendicular to the first direction, the dielectric material separating a first memory cell of the two or more respective memory cells from a second memory cell of the two or more respective memory cells at each of the plurality of levels; and a plurality of control gates each associated with accessing a respective memory cell of the plurality of levels of memory cells, where each control gate of the plurality of control gates includes a first metal and a second metal.

Aspect 24: The apparatus of aspect 23, further including: a plurality of access lines including the first metal, the second metal, or both, where each access line of the plurality of access lines includes a respective control gate of the plurality of control gates.

Aspect 25: The apparatus of any of aspects 23 through 24, further including: a first pillar of charge trapping material extending alongside the conductive pillar in the first direction and associated with the first memory cell of the two or more respective memory cells at each level of the plurality of levels; and a second pillar of charge trapping material extending alongside the conductive pillar in the first direction and associated with the second memory cell of the two or more respective memory cells at each level of the plurality of levels.

Aspect 26: The apparatus of any of aspects 23 through 25, where the first metal is associated with a first resistivity and the second metal is associated with a second resistivity different than the first resistivity.

Aspect 27: The apparatus of any of aspects 23 through 26, where the first metal is associated with a first work function and the second metal is associated with a second work function different than the first work function.

Aspect 28: The apparatus of any of aspects 23 through 27, where a first length of the first metal in a third direction perpendicular to the first direction and the second direction and a second length of the second metal in the third direction are based at least in part on one or more dimensions of a planar region of the respective memory cells, one or more dimensions of a curved region of the respective memory cells, or both.

Aspect 29: The apparatus of any of aspects 23 through 28, where each control gate of the plurality of control gates includes one or more additional metals different than the first metal material and the second metal material.

Aspect 30: The apparatus of any of aspects 23 through 29, further including: one or more pillars of dielectric material extending through the plurality of levels of memory cells in the first direction, the first metal and the second metal in contact with a pillar of dielectric material located between a respective memory cell and the first metal and the second metal.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a 3D structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a stack of materials over a substrate, the stack comprising a plurality of layers of a first material and a plurality of layers of a second material;
forming, through the stack of materials in a first direction perpendicular to the substrate, a plurality of first cavities;
forming, in the plurality of first cavities, respective pillars of charge trapping material and respective conductive pillars each extending in the first direction;
removing the plurality of layers of the second material to form a plurality of second cavities at respective locations of the removed layers of the second material;
forming, in the plurality of second cavities, respective layers of a first metal;
forming, through at least the stack of materials, a trench in the first direction and extending in a second direction parallel to the substrate;
removing, using the trench, respective portions of the respective layers of the first metal to form a plurality of third cavities extending in a third direction parallel to the substrate; and
forming, in the plurality of third cavities, respective layers of a second metal, wherein the respective layers of the first metal and the second metal form respective access lines associated with accessing respective memory cells associated with the respective pillar of charge trapping material.

2. The method of claim 1, further comprising:
forming, after forming the respective layers of the second metal, a dielectric material in the trench.

3. The method of claim 1, wherein forming the trench comprises:
forming the trench through the respective pillars of charge trapping material and the respective conductive pillars, each respective pillar of charge trapping material being separated into a first pillar of charge trapping material on a first side of the trench and a second pillar of charge trapping material on a second side of the trench, wherein the first pillar of charge trapping material is associated with a first set of the respective memory cells and the second pillar of charge trapping material is associated with a second set of the respective memory cells.

4. The method of claim 3, further comprising:
determining, based at least in part on one or more dimensions of the respective first pillars of charge trapping material, a depth of one or more of the plurality of third cavities, wherein removing the respective portions of the respective layers of the first metal is based at least in part on determining the depth.

5. The method of claim 1, further comprising:
determining, based at least in part on one or more dimensions of a planar region of the respective memory cells, one or more dimensions of a curved region of the respective memory cells, or both, a quantity of the first metal to remove, wherein removing the respective portions of the respective layers of the first metal is based at least in part on determining the quantity.

6. The method of claim 5, further comprising:
selecting, based at least in part on the one or more dimensions of the curved region of the respective memory cells, the first metal to form in the plurality of second cavities based at least in part on a first electric field created by the first metal; and
selecting, based at least in part on one the one or more dimensions of the planar region of the respective memory cells, the second metal to form in the plurality of third cavities based at least in part on a second electric field created by the second metal, wherein the second electric field is stronger than the first electric field.

7. The method of claim 1, wherein the first metal is associated with a first work function, the second metal is associated with a second work function greater than the first work function, the first metal is associated with a first resistivity, the second metal is associated with a second resistivity different than the first resistivity, or a combination thereof.

8. An apparatus, comprising:
a conductive pillar extending in a first direction perpendicular to a substrate and through a plurality of levels of memory cells located over the substrate, the conductive pillar coupled with two or more respective memory cells at each of the plurality of levels;
a dielectric material extending in a second direction parallel to the substrate, the dielectric material separating a first memory cell of the two or more respective memory cells from a second memory cell of the two or more respective memory cells at each level of the plurality of levels; and
a plurality of access lines extending in the second direction and associated with accessing the plurality of levels of memory cells, wherein each access line of the plurality of access lines coupled with a respective memory cell comprises:
a first metal associated with a first resistivity; and
a second metal associated with a second resistivity different than the first resistivity.

9. The apparatus of claim 8, further comprising:
a first pillar of charge trapping material extending in the first direction and associated with the first memory cell of the two or more respective memory cells at each level of the plurality of levels; and
a second pillar of charge trapping material extending in the first direction and associated with the second memory cell of the two or more respective memory cells at each level of the plurality of levels.

10. The apparatus of claim 8, wherein each access line of the plurality of access lines comprises a respective gate comprising the first metal and the second metal.

11. The apparatus of claim 8, wherein a first length of the first metal in a third direction parallel to the substrate and perpendicular to the second direction and a second length of the second metal in the third direction are based at least in part on one or more dimensions of a planar region of the respective memory cells, one or more dimensions of a curved region of the respective memory cells, or both.

12. The apparatus of claim 8, wherein the first metal is configured to create a first electric field and the second metal is configured to create a second electric field that is stronger than the first electric field.

13. The apparatus of claim 8, wherein the first metal is associated with a first work function and the second metal is associated with a second work function different than the first work function.

14. The apparatus of claim 8, wherein each access line of the plurality of access lines comprises one or more additional metals different than the first metal and the second metal.

15. The apparatus of claim 8, wherein the first metal is configured to create a first electric field and the second metal is configured to create a second electric field stronger than the first electric field.

16. An apparatus, comprising:
a conductive pillar extending in a first direction through a plurality of levels of memory cells and coupled with two or more respective memory cells at each of the plurality of levels;
a dielectric material extending in a second direction perpendicular to the first direction, the dielectric material separating a first memory cell of the two or more respective memory cells from a second memory cell of the two or more respective memory cells at each of the plurality of levels; and
a plurality of control gates each associated with accessing a respective memory cell of the plurality of levels of memory cells, wherein each control gate of the plurality of control gates comprises a first metal and a second metal.

17. The apparatus of claim 16, further comprising:
a plurality of access lines comprising the first metal, the second metal, or both, wherein each access line of the plurality of access lines comprises a respective control gate of the plurality of control gates.

18. The apparatus of claim 16, further comprising:
a first pillar of charge trapping material extending alongside the conductive pillar in the first direction and associated with the first memory cell of the two or more respective memory cells at each level of the plurality of levels; and
a second pillar of charge trapping material extending alongside the conductive pillar in the first direction and associated with the second memory cell of the two or more respective memory cells at each level of the plurality of levels.

19. The apparatus of claim 16, wherein the first metal is associated with a first resistivity, the second metal is associated with a second resistivity different than the first resistivity, the first metal is associated with a first work function, the second metal is associated with a second work function different than the first work function, or a combination thereof.

20. The apparatus of claim 16, wherein a first length of the first metal in a third direction perpendicular to the first direction and the second direction and a second length of the second metal in the third direction are based at least in part on one or more dimensions of a planar region of the respective memory cells, one or more dimensions of a curved region of the respective memory cells, or both.
